(19) United States
(12) Patent Application Publication
(10) Pub. No.: US 2025/0347711 A1
(43) Pub. Date: Nov. 13, 2025

(54) MOLDED COMPONENT

(71) Applicant: Sumitomo Wiring Systems, Ltd., Yokkaichi-shi, Mie (JP)

(72) Inventors: Lin WEI, Yokkaichi-Shi, Mie (JP); Hiroyuki KOYANO, Yokkaichi-Shi, Mie (JP); Yukitoshi TERASAKA, Yokkaichi-Shi, Mie (JP); Toshinari KOBAYASHI, Yokkaichi-Shi, Mie (JP); Megumi YAMAO, Yokkaichi-Shi, Mie (JP)

(73) Assignee: Sumitomo Wiring Systems, Ltd., Yokkaichi-Shi, Mie (JP)

(21) Appl. No.: 18/869,895

(22) PCT Filed: May 18, 2023
(86) PCT No.: PCT/JP2023/018593

§ 371 Date: Nov. 27, 2024

(30) Foreign Application Priority Data
May 30, 2022 (JP) 2022-087441

(51) Int. Cl. G01P 1/02; G01P 3/44

(52) U.S. Cl. CPC G01P 1/026; G01P 3/44

(57) ABSTRACT

A molded component includes: an internal component including an electronic component body (detector element body) and a lead wire extending from the electronic component body (detector element body); a connection terminal connected to the lead wire a first molded part covering the internal component and holding the connection terminal, and a second molded part covering the first molded part. The second molded part has a non-water-exposed region located in a region where water exposure is suppressed, and a through-hole (outer through-hole) extending from a surface of the second molded part to reach the first molded part is formed only in the non-water-exposed region of the second molded part.

### CROSS-REFERENCE TO RELATED APPLICATIONS

This application is the U.S. national stage of PCT/JP2023/018593 filed on May 18, 2023, which claims priority of Japanese Patent Application No. JP 2022-087441 filed on May 30, 2022, the contents of which are incorporated herein.

### TECHNICAL FIELD

The present disclosure relates to a molded component.

### BACKGROUND

Vehicles such as automobiles are equipped with wheel speed sensors that measure the rotational speed of wheels. A device such as that described in JP 2017-096828A is known as this type of wheel speed sensor. The wheel speed sensor described in JP 2017-096828A includes a plurality of detector elements and a holder that holds the plurality of detector elements. The holder is injection molded with the detector elements held in a predetermined arrangement. The detector elements and the holder are covered by a resin molded part to form a molded body.

Here, to fix the holder as an insert using a pin when molding the resin molded part, a through-hole that extends from an outer surface of the resin molded part to the holder is formed in the resin molded part. It is desired to further suppress water exposure of the internal components.

It is an object to provide a molded component with which water exposure of the internal components is further suppressed.

### SUMMARY

A molded component of the present disclosure includes: an internal component including: an electronic component body; and a lead wire extending from the electronic component body; a connection terminal connected to the lead wire; a first molded part covering the internal component and holding the connection terminal; and a second molded part covering the first molded part, wherein the second molded part has a non-water-exposed region located in a region where water exposure is suppressed, and a through-hole extending from a surface of the second molded part to reach the first molded part is formed only in the non-water-exposed region of the second molded part.

### Advantageous Effects

According to the present disclosure, the entry of water into the through-holes, which are formed only in the non-water-exposed region, is suppressed. This further suppresses water exposure of the internal components through the through-holes.

### BRIEF DESCRIPTION OF DRAWINGS

FIG. 1 is a perspective view of a molded component.

FIG. 2 is a perspective view of the molded component without a second molded part.

FIG. 3 is a partial enlarged view of a portion of a joint section of a first molded part together with exposed sections of lead wires and exposed sections of connection terminals.

FIG. 4 is a partial enlarged view of a portion of the joint section of the first molded part together with the exposed sections of the lead wires and the exposed sections of the connection terminals.

FIG. 5 is a plan view of the molded component attached to an attachment target component together with a portion of the attachment target component.

FIG. 6 is a side view of the molded component attached to the attachment target component together with a portion of the attachment target component.

FIG. 7 is a diagram illustrating a process of producing the molded component.

FIG. 8 is a diagram illustrating a process of producing the molded component.

### DETAILED DESCRIPTION OF PREFERRED EMBODIMENTS

Firstly, modes for carrying out the present disclosure are listed and described.

A molded component of the present disclosure is as follows.

In a first aspect, a molded component includes: an internal component including: an electronic component body; and a lead wire extending from the electronic component body; a connection terminal connected to the lead wire; a first molded part covering the internal component and holding the connection terminal; and a second molded part covering the first molded part, wherein the second molded part has a non-water-exposed region located in a region where water exposure is suppressed, and a through-hole extending from a surface of the second molded part to reach the first molded part is formed only in the non-water exposed region of the second molded part.

With this molded component, the first molded part is a single part covering the internal component and holding the connection terminal. Thus, when the second molding part is molded, the internal component covered by the first molding part and the connection terminal held by the first molded part can be positioned within the second molded part by using the through-holes formed in the non-water-exposed region.

Further, water is unlikely to enter the through-holes themselves since the through-holes, which can be used to position the first molded part that is a single component covering the internal component and holding the connection terminal, are formed only in the non-water-exposed region. This also makes it unlikely for water to enter between the first and second molded parts. Water exposure of the internal component is thus suppressed.

Further, the internal component and the connection terminal can be molded in the first molded part, which is a single component, so that the production person-hours can be reduced compared to molding the internal component and the connection terminal separately.

In a second aspect, in the molded component of the the first aspect, the first molded part may include: a head covering the electronic component body; a connection terminal holder holding a portion of the connection terminal; and a joint section joining the head to the connection terminal holder, the lead wire and the connection terminal may each have, in the joint section, an exposed section exposed from the first molded part, the exposed section of the lead wire and the exposed section of the connection terminal may be connected to each other by solder in the joint section, and the second molded part may cover the exposed section of the lead wire, the exposed section of the connection terminal, and the solder connecting the exposed section of the lead wire and the exposed section of the connection terminal to each other, in the joint section.

This molded component facilitates soldering since the lead wire and the connection terminal each have the exposed section in the joint section.

Further, the lead wire and the connection terminal are connected more reliably due to the second molded part covering the solder. In addition, water exposure of the exposed section of the lead wire, the exposed section of the connection terminal, and the solder is suppressed since the second molded part covers the exposed section of the lead wire, the exposed section of the connection terminal, and the solder.

In a third aspect, in the molded component of the first or the second aspects, the connection terminal may have a connector exposed section exposed from the first molded part and the second molded part, and the connector exposed section may be a connecting section to be connected to a connector connectable to another electrical component.

With this molded component, the first molded part holds the connector exposed section at a fixed position suitable for connection with a connector. This allows the connector exposed section to be easily connected to the connector.

In a fourth aspect, in the molded component of any of the first through the third aspects, the non-water-exposed region may include a region covering the electronic component body.

With this molded component, the non-water-exposed region includes the region covering the electronic component body, and the through-holes are therefore formed in the region covering the electronic component body (the region covering the head). Thus, the portion of the first molded part that covers the electronic component body can easily be positioned within the second molded part using the through-holes. This improves the position accuracy of the electronic component body within the first and second molded parts.

In a fifth aspect, in the molded component of any of the first through the fourth aspects, an O-ring may be attached to an outer periphery of the second molded part, and the O-ring may separate the non-water-exposed region from a region other than the non-water-exposed region.

With this molded component, the non-water-exposed region is provided by the waterproofing effect of the O-ring. The second molded part has the through- holes only in this non-water-exposed region. Water exposure of the internal component is thus suppressed.

In a sixth aspect, in the molded component of any of the first through the fifth aspects, the second molded part may have a first face and a second face oriented in a direction opposite to a direction in which the first face is oriented, the through-hole may be formed in both the first face and the second face, and the through-hole may include at least two through-holes formed in the first face.

With this molded component, the through-holes are formed in both the first and second faces, allowing the first molded part to be positioned using the through-holes in the direction connecting the first face and the second face. Further, two or more through-holes are formed in the first face, thus suppressing a rotational shift of the first molded part as an insert when the second molded part is molded.

Specific examples of the molded component of the present disclosure are described below with reference to the drawings. Note that the present disclosure is not limited to these examples but is defined by the claims, and is intended to include all changes made within the meaning and scope equivalent to the claims.

Note that the drawings are schematic illustrations, and configurations may be omitted or simplified in the drawings as appropriate for convenience of description. The interrelationships in sizes and positions between components shown in different drawings are not necessarily described accurately and may be changed as appropriate. In not only cross-sectional views but also diagrams such as plan views, hatching may be used to facilitate understanding of the content of the embodiments.

In the following description, like constituent elements are assigned like reference numerals, and their names and functions are also the same. Therefore, detailed descriptions thereof may be omitted to avoid redundancy.

### First Embodiment

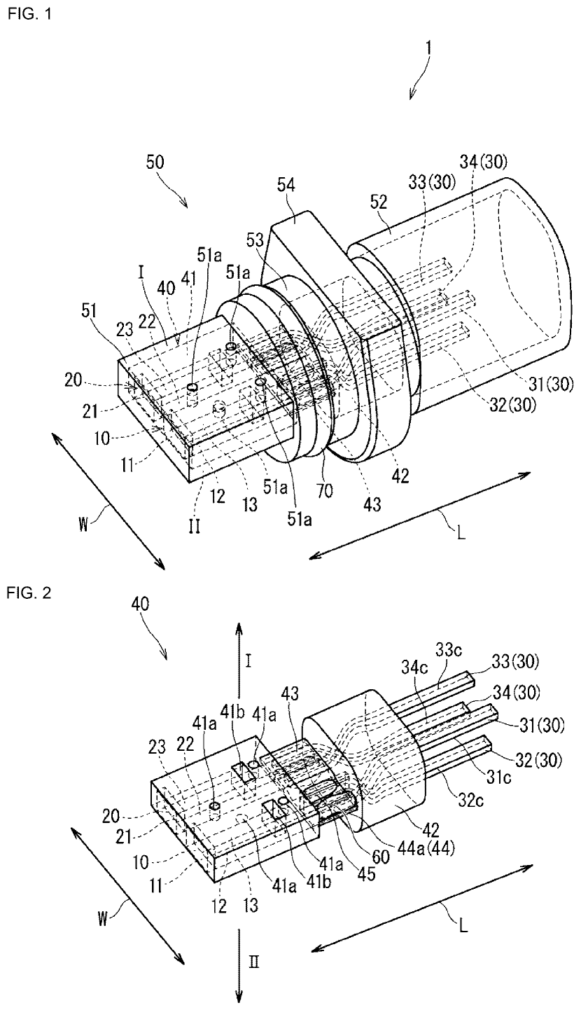

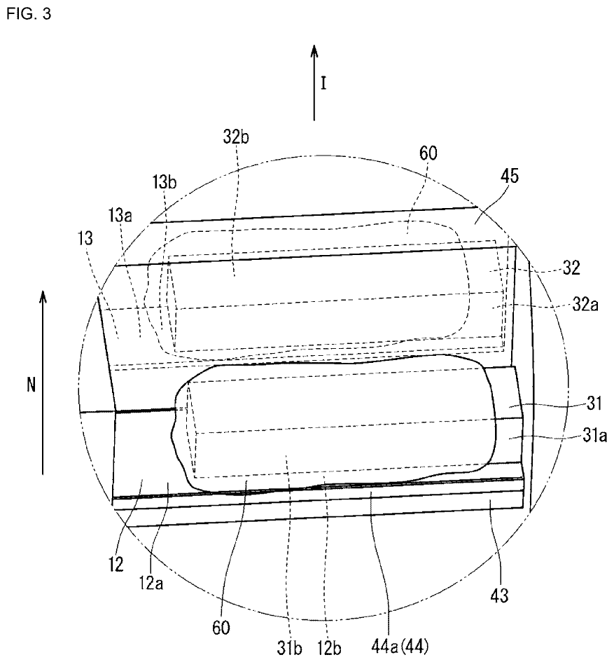

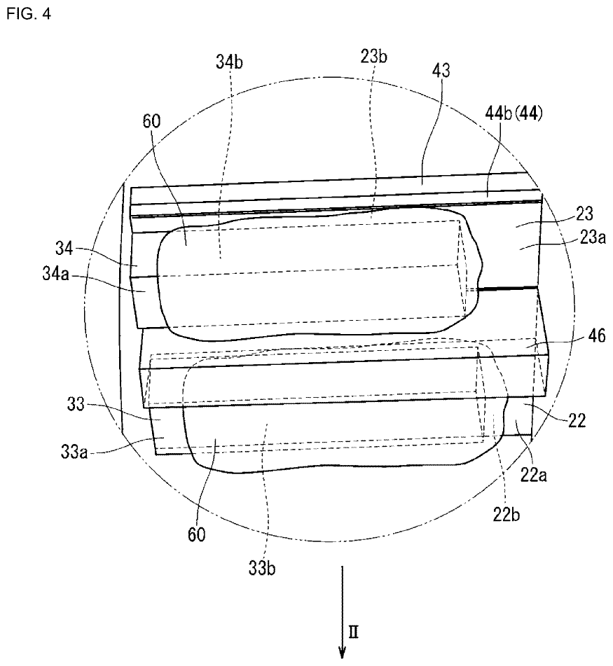

A molded component 1 related to the present embodiment will be described below. FIG. 1 is a perspective view of the molded component 1. FIG. 2 is a perspective view of the molded component 1 excluding a second molded part 50. FIG. 3 is a partial enlarged view of a portion of a joint section 43 of a first molded part 40 together with exposed sections 12a and 13a of lead wires 12 and 13 and exposed sections 31a and 32a of connection terminals 30. FIG. 4 is a partial enlarged view of a portion of the joint section 43 of the first molded part 40 together with the exposed sections 22a and 23a of the lead wires 22 and 23 and the exposed sections 34a and 33a of the connection terminals 30. FIG. 3 is a perspective view from a first face I side, and FIG. 4 is a perspective view from a second face II side. In the figures and the following description, L denotes the lengthwise direction of the molded component 1, and W denotes the widthwise direction thereof.

### Configuration of Molded Component 1

The molded component 1 is used, for example, to measure the rotational speed of a vehicle tire. The molded component 1 detects, for example, magnetic field fluctuations due to a rotation of a detection target that rotates with the rotation of a tire. The molded component 1 includes two internal components 10 and 20, connection terminals 30 connected to the internal components 10 and 20, a first molded part 40 covering the internal components 10 and 20 and holding the connection terminals 30, and a second molded part 50 covering the first molded part 40. Note that the second molded part 50 has a first face I and a second face II that is oriented in a direction opposite to the direction in which the first face I is oriented.

### Configuration of Internal Components 10 and 20

The internal component 10 has a detector element body 11, which is an electronic component body, and a plurality of (here, two) lead wires 12 and 13 extending from the detector element body 11. The two lead wires 12 and 13 are arranged side by side with a gap therebetween. The internal component 20 has the same configuration as the internal component 10. The internal component 20 has a detector element body 21, which is an electronic component body, and a plurality of (here, two) lead wires 22 and 23.

The internal components 10 and 20 are arranged in the widthwise direction W of the molded component 1. The four lead wires 12, 13, 22, and 23 extend parallel with each other in the lengthwise direction L of the molded component 1.

The detector element bodies 11 and 21 detect, for example, magnetic field fluctuations due to a rotation of a detection target that rotates with the rotation of The detector element bodies 11 and 21 may detect magnetic field a tire. fluctuations around the detector element bodies 11 and 21 that occur with a movement of a magnet attached to a rotor in a magnet encoder, for example. The detector element bodies 11 and 21 output electrical signals corresponding to such magnetic field fluctuations (wheel rotation speed). The detector element bodies 11 and 21 are, for example, disposed at different positions in the rotational direction of the detection target, and thus generate electrical signals at different timings. The electrical signals output from the detector element bodies 11 and 21 are transmitted to the connection terminals 30 via the lead wires 12, 13, 22, and 23. The electrical signals transmitted to the connection terminals 30 are input to another electrical component (e.g., a control unit or a control device).

The lead wires 12, 13, 22, and 23 each have, for example, a thin rectangular plate shape. The lead wires 12 and 13 extend in parallel from the detector element body 11, and the lead wires 22 and 23 extend in parallel from the detector element body 21. The detector element bodies 11 and 21 are adjacent to each other with a gap therebetween. The detector element bodies 11 and 21 are in the same orientation within the first molded part 40. Thus, the lead wires 12, 13, 22, and 23 are parallel with each other as a whole. As shown in FIG. 3, leading ends of the lead wires 12 and 13 have exposed sections 12a and 13a that are exposed from the first molded part 40. The exposed sections 12a and 13a of the lead wires 12 and 13 have portions serving as lead wire soldering sections 12b and 13b. The lead wires 12 and 13 and the connection terminals 30 are soldered and connected by solder 60 at the lead wire soldering sections 12b and 13b of the lead wires 12 and 13.

Similar to the lead wires 12 and 13, the lead wires 22 and 23 also have exposed sections 22a and 23a that are exposed from the first molded part 40, as shown in FIG. 4. The exposed sections 22a and 23a of the lead wires 22 and 23 have portions serving as lead wire soldering sections 22b and 23b. The lead wires 22 and 23 and the connection terminals 30 are soldered and connected by the solder 60 at the lead wire soldering sections 22b and 23b of the lead wires 22 and 23.

### Configuration of Connection Terminals 30

The connection terminals 30 include four connection terminals 31, 32, 33, and 34. The connection terminals 30 are made of, for example, a metallic material such as copper, a copper alloy, aluminum, an aluminum alloy, or stainless steel. The connection terminals 30 are formed, for example, by pressing a metal plate having a good conductivity. It is preferable that the connection terminals 30 are rigid to the extent that they can maintain their orientation in a constant shape.

The connection terminals 31, 32, 33, and 34 are connected to the lead wires 12, 13, 22, and 23, respectively. As shown in FIGS. 1 and 2, one end of each of the connection terminals 31, 32, 33, and 34 is exposed from the first molded part 40 to form exposed sections 31a, 32a, 33a, and 34a.

Here, the connection terminals 31 and 32 of the connection terminals 30 are described. As shown in FIG. 3, the exposed sections 31a and 32a of the connection terminals 31 and 32 have connection terminal soldering sections 31b and 32b. The connection terminal soldering sections 31b and 32b are connected to the aforementioned lead wire soldering sections 12b and 13b by the solder 60. The connection between the connection terminals 33 and 34 and the lead wires 22 and 23 is the same as the connection between the connection terminals 31 and 32 and the lead wires 12 and 13, and a description thereof is accordingly omitted. Note that the connection terminal soldering sections 33b and 34b shown in FIG. 4 have the same configuration as the connection terminal soldering sections 31b and 32b.

The connection terminals 31, 32, 33, and 34 have connector exposed sections 31c, 32c, 33c, and 34c exposed from the first molded part 40 and the second molded part 50. Specifically, the other ends of the connection terminals 31, 32, 33, and 34 on the side different from the exposed sections 31a, 32a, 33a, and 34a side are exposed from the first molded part 40 and the second molded part 50, and constitute the connector exposed sections 31c, 32c, 33c, and 34c. The connector exposed sections 31c, 32c, 33c, and 34c are connection sections for connection to a connector connectable to another electrical component. The molded component 1 itself thus has a configuration having a connector due to these connector exposed sections 31c, 32c, 33c, and 34c. This allows the molded component 1 itself to be directly connected to a connector extending from another electrical component (e.g., a control unit or a control device).

### First Molded Part 40

The first molded part 40 has a head 41, a connection terminal holder 42, and a joint section 43 that joins the head 41 to the connection terminal holder 42. The first molded part 40 is made of, for example, resin. The first molded part 40 is a part formed by molding a resin material with the internal components 10 and 20 as inserts.

The head 41 covers the detector element bodies 11 and 21. The head 41 includes recesses 41a and inner through-holes 41b that extend from a surface of the first molded part 40 to the internal components 10 and 20.

The head 41 of the first molded part 40 has a plurality of (here, three) recesses 41a on the first face I side of the second molded part 50, and at least one (here, one) recess 41a on the second face II side of the second molded part 50. The recesses 41a are portions into which leading ends of positioning pins for fixing the first molded part 40 is inserted when the second molded part 50 is molded. That is, the recesses 41a are portions into which the positioning pins of a mold device are inserted when molding is performed using the first molded part 40 as an insert. The recesses 41a are recesses that are open in the surface of the first molded part 40 but do not reach the surfaces of the internal components 10 and 20.

The head 41 of the first molded part 40 has a plurality of (here, two) inner through-holes 41b on the first face I side of the second molded part 50. The inner through-holes 41b are marks of positioning pins for fixing portions of the internal components 10 and 20 when the first molded part 40 is molded. When the first molded part 40 is removed from the mold, the inner through-holes 41b are formed as marks of the positioning pins. The inner through-holes 41b extend to the surfaces of the internal components 10 and 20, and portions of the surfaces of the internal components 10 and 20 are exposed within the inner through-holes 41b. In the present embodiment, for example, the positioning pins press and fix the area of the lead wires 12, 13, 22, and 23 of the internal components 10 and 20. The inner through-holes 41b are formed so as to expose portions of the lead wires 12, 13, 22, and 23. As a result, the lead wires 12, 13, 22, and 23, which are fixed by the positioning pins when the first molded part 40 is molded, are exposed to the outside of the first molded part 40 through the inner through-holes 41b. Similarly, holes are also formed on the second face II side of the molded component 1 as marks of holding parts for holding the internal components 10 and 20, but are omitted in the figures.

The connection terminal holder 42 holds portions of the connection terminals 30. The connection terminal holder 42 holds a plurality of (here, four) connection terminals 31, 32, 33, and 34 at fixed positions. The exposed sections 31a, 32a, 33a, and 34a and the connector exposed sections 31c, 32c, 33c, and 34c are thus held at fixed positions. As a result, the connector exposed sections 31c, 32c, 33c, and 34c are held at fixed positions suitable for connection with a connector of another electrical component. For example, the connector exposed sections 31c, 32c, 33c, and 34c are held in orientations parallel with each other and protruding in the same direction. Further, the exposed sections 31a, 32a, 33a, and 34a are held at fixed positions suitable for connection with the lead wires 12, 13, 22, and 23 (e.g., positions abutting the lead wires 12, 13, 22, and 23 on the opposite side to the joint section 43).

The joint section 43 joins the head 41 to the connection terminal holder 42 such that the connection terminal holder 42 is held at a fixed position relative to the head 41. The joint section 43 may be thinner than the head 41 and the connection terminal holder 42.

The joint section 43 in the present embodiment has placement sections 44 that correspond to the respective lead wires 12, 13, 22, and 23. Each placement section 44 has a first placement surface 44a, which is oriented in the first face direction of the molded component 1, and a second placement surface 44b, which is oriented in the second face direction of the molded component 1. The second placement surface 44b is oriented in a direction opposite to the direction in which the first placement surface 44a is oriented. The placement sections 44 also serve as partitions between the lead wires 12 and 13 and the lead wires 22 and 23.

In the present embodiment, the normal directions (arrow N in FIG. 3) of the first placement surface 44a and the second placement surface 44b are the same. The lead wires 12 and 13 are placed on the first placement surface 44a, and the lead wires 22 and 23 are placed on the second placement surface 44b. Since the lead wires 12 and 13 are disposed on the first placement surface 44a and the lead wires 22 and 23 are disposed on the second placement surface 44b, the solder 60 (see FIG. 3) on the lead wires 12 and 13 and the solder 60 (see FIG. 4) on the lead wires 22 and 23 do not come into contact with each other. This prevents a short circuit between the lead wires 12 and 13 and the lead wires 22 and 23.

A first separation wall 45 is disposed between the lead wires 12 and 13 to separate the lead wires 12 and 13 from each other. This first separation wall 45 prevents the solder 60 on the lead wire 12 and the solder 60 on the lead wire 13 from coming into contact with each other. In addition, the lead wires 12 and 13 do not come into contact with each other either. This prevents a short circuit between the lead wires 12 and 13.

Similarly, a second separation wall 46 is disposed between the lead wires 22 and 23 to separate the lead wires 22 and 23 from each other. This second separation wall 46 prevents the solder 60 on the lead wire 22 and the solder 60 on the lead wire 23 from coming into contact with each other. In addition, the lead wires 22 and 23 do not come into contact with each other either. This prevents a short circuit between the lead wires 22 and 23.

### Second Molded Part 50

The second molded part 50 covers the first molded part 40. The second molded part 50 includes a head cover 51 covering the head 41 of the first molded part 40, a tubular section 52 that surrounds portions of the connection terminals 30, and a joint section 53 that joins the head cover 51 to the tubular section 52. The second molded part 50 also includes an annular protrusion 54 that protrudes outward from an outer periphery of the joint section 53.

The head cover 51 of the second molded part 50 has a plurality of (here, three) outer through-holes 51a on the first face I side, and at least one (here, one) outer through-hole 51a on the second face II side. The outer through-holes 51a are marks of positioning pins for fixing portions of the first molded part 40 when the second molded part 50 is molded. When the second molded part 50 is removed from a mold, the outer through-holes 51a are formed as marks of the positioning pins. The outer through-holes 51a extend to the surface of the first molded part 40, and portions of the first molded part 40 are exposed within the outer through-holes 51a. In the present embodiment, the positioning pins engage with the recesses 41a of the first molded part 40 to fix the first molded part 40. Thus, the recesses 41a, which are fixed by the positioning pins when the second molded part 50 is molded, are exposed to the outside of the second molded part 50 through the outer through-holes 51a.

The tubular section 52 surrounds the connector exposed sections 31c, 32c, 33c, and 34c of the connection terminals 30. The tubular section 52 and the connector exposed sections 31c, 32c, 33c, and 34c are formed in shapes suitable for engaging with a mating connector connected to another electrical component. For example, the mating connector has a plurality of mating terminal sections connectable to the connector exposed sections 31c, 32c, 33c, and 34c. Each mating terminal sections is formed, for example, in a columnar terminal shape. The mating connector has a housing section that holds the plurality of mating terminal sections at positions corresponding to the positions of the respective connector exposed sections 31c, 32c, 33c, and 34c. The tubular section 52 is formed in a tubular shape into which the housing section of the mating connector can be inserted. Thus, the tubular section 52 and the connector exposed sections 31c, 32c, 33c, and 34c are directly connected to the mating connector connected to another electrical component.

The joint section 53 is located between the head cover 51 and the tubular section 52. The joint section 53 covers the exposed sections 12a, 13a, 22a, and 23a of the lead wires 12, 13, 22, and 23, the connector exposed sections 31c, 32c, 33c, and 34c of the connection terminals 31, 32, 33, and 34, and the solder 60. With this, the lead wires 12, 13, 22, and 23, the connection terminals 30, and the solder 60 are covered by the second molded part 50 and are not exposed to the outside of the molded component 1.

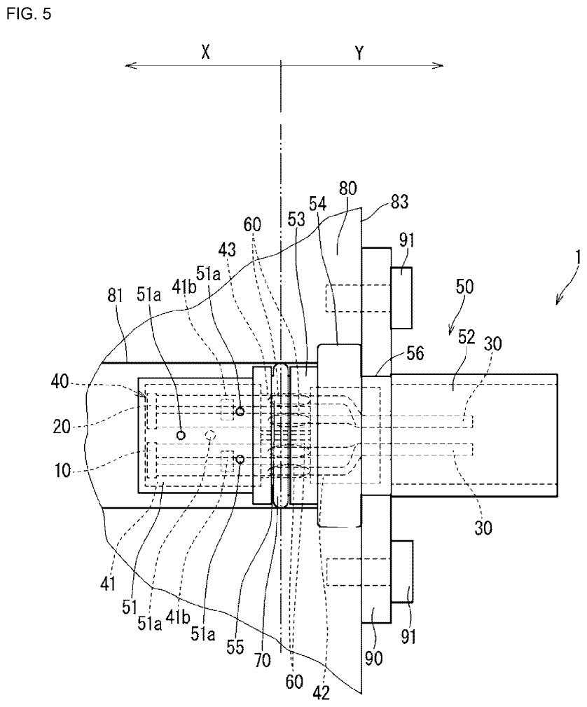

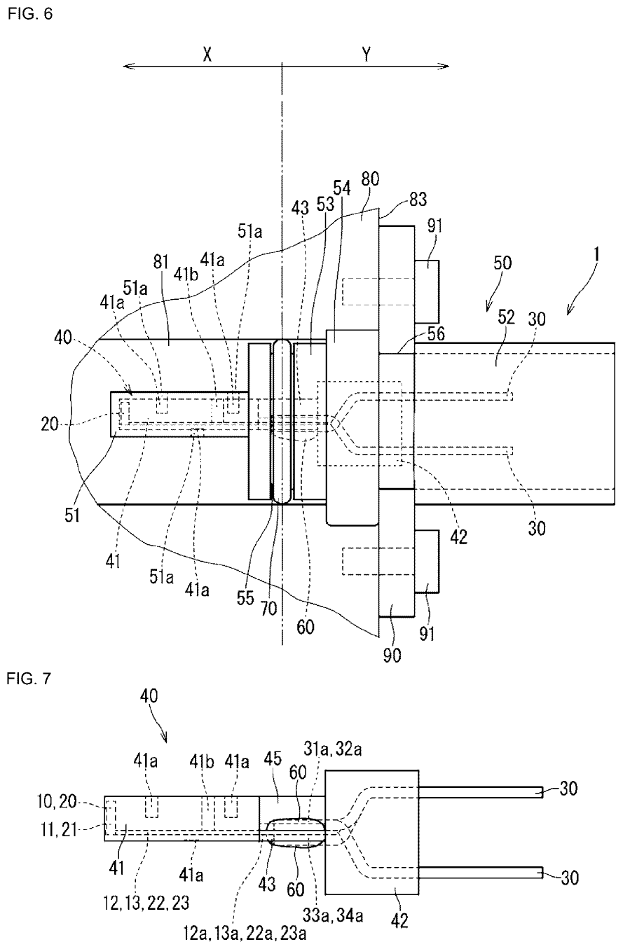

An O-ring 70 is attached to a peripheral portion of the joint section 53 on the side closer to the head cover 51 than to the annular protrusion 54. The O-ring 70 is fitted into a fitting groove 55 (see FIGS. 5 and 6) formed in the joint section 53. The O-ring 70 is an annular member made of an elastic material such as rubber.

### Arrangement of Molded Component 1

FIG. 5 is a plan view of the molded component 1 attached to an attachment target component 80 together with a portion of the attachment target component 80. FIG. 6 is a side view of the molded component 1 attached to the attachment target component 80 together with a portion of the attachment target component 80.

As shown in FIGS. 5 and 6, the molded component 1 is attached to the attachment target component 80 by inserting at least a portion of the molded component 1 into a hole 81 in the attachment target component 80. In the present embodiment, the head cover 51 and a portion of the joint section 53 are inserted into the hole 81 in the attachment target component 80. For example, a large diameter section for receiving the annular protrusion 54 is formed in the opening of the hole 81 in the attachment target component 80. The large diameter section has a shape that matches the shape of the annular protrusion 54, and the annular protrusion 54 is fitted into the large-diameter section.

The O-ring 70 is fitted into the fitting groove 55 formed on the side closer to the head cover 51 than to the annular protrusion 54. The outer periphery of the O-ring 70 comes into contact with the inner periphery of the hole 81 in a liquid-tight state. This suppresses the entry of water from the tubular section 52 side relative to the O-ring 70 to the head cover 51 side relative to the O-ring 70. Therefore, even if water enters from an outer surface 83 of the attachment target component 80 to the head cover 51 side, the entry of water from the tubular section 52 side to the head cover 51 side is suppressed, with the O-ring 70 as a boundary.

In the second molded part 50, a region X where the entry of water is suppressed as mentioned above (hereinafter referred to as a “non-water-exposed region X”) is set on the head cover 51 side, with the O-ring 70 as a boundary (see

FIGS. 5 and 6). That is, as shown in FIGS. 5 and 6, the O-ring 70 divides the second molded part 50 into the non-water-exposed region X and the other region (hereinafter referred to as a “water-exposed region Y”).

In the present embodiment, an engagement groove section 56 is formed at the outer periphery of the second molded part 50 on the side closer to the tubular section 52 than to the annular protrusion 54. A locking member 90 is joined to the periphery of the engagement groove section 56. The locking member 90 is fixed to the outer surface 83 of the attachment target component 80 by screws 91. The molded component 1 is thus fixed to the attachment target component 80. Preferably, the surface of the locking member 90 that comes into contact with the outer surface 83 of the attachment target component 80 has a shape that matches the shape of the outer surface 83 of the attachment target component 80. The surface of the locking member 90 and the outer surface 83 of the attachment target component 80 thus come into intimate contact with each other. The locking member 90 and the outer surface 83 of the attachment target component 80 also further suppress the entry of water from the tubular section 52 side to the head cover 51 side, with the outer surface 83 of the attachment target component 80 as a boundary. Note that a seal member may also be held between the locking member 90 and the outer surface 83. With this configuration, even if the surface of the locking member 90 and the outer surface 83 of the attachment target component 80 are not shaped so as to come into intimate contact with each other, the effect of the seal member further suppresses the entry of water from the tubular section 52 side to the head cover 51 side, with the outer surface 83 of the attachment target component 80 as a boundary.

In the present embodiment, the non-water-exposed region X includes a region covering electronic component bodies (the detector element bodies 11 and 21). In the present embodiment, the entire head cover 51 of the first molded part 40 that covers the electronic component bodies (the detector element bodies 11 and 21) is located within the non-water-exposed region X. Further, the outer through-holes 51a are formed only in the head cover 51. That is, the outer through-holes 51a are formed only in the non-water-exposed region of the second molded part. This makes it difficult for water to enter the outer through-holes 51a.

Further, the inner through-holes 41b in the first molded part 40 are also formed only in the head 41. That is, in the present embodiment, the outer through-holes 51a and the inner through-holes 41b are formed at positions close to each other. Even if the outer through-holes 51a and the inner through-holes 41b are formed in such an arrangement, the entry of water into the outer through-holes 51a is suppressed, and therefore the entry of water into the inner through-holes 41b is also suppressed.

Furthermore, since the outer through-holes 51a in the second molded part 50 are formed only around the region covering the electronic component bodies (the detector element bodies 11 and 21), the shape of second molded part 50 can be simplified.

### Production Method of Molded Component 1

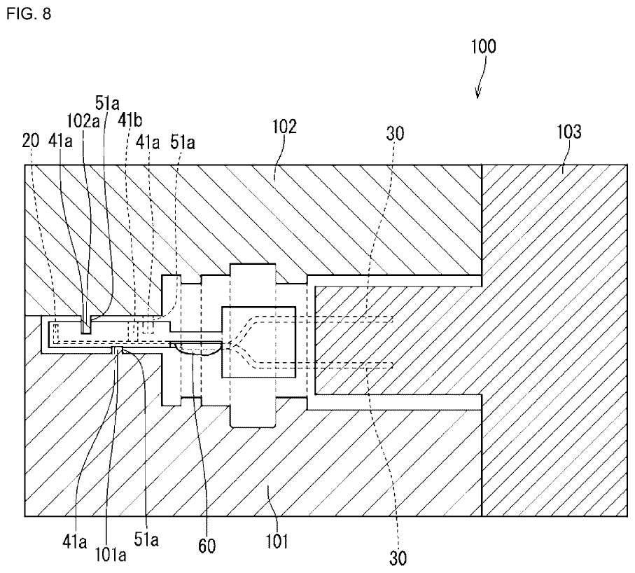

FIGS. 7 and 8 are diagrams illustrating a process of producing the molded component 1. FIG. 7 shows from the side that after the first molded part 40 has been molded, the lead wires 12, 13, 22, and 23 and the connection terminals 30 are connected by the solder 60. FIG. 8 shows a side cross-section of the first molded part 40 and the solder 60 that are set in a mold device 100 when the second molded part 50 is molded with the first molded part 40 as an insert after the process shown in FIG. 7.

As shown in FIG. 7, first, the internal components 10 and 20 and the connection terminals 30 are fixed by the first molded part 40 so as to be located at respective predetermined positions. The exposed sections 12a, 13a, 22a, and 23a of the lead wires 12, 13, 22, and 23 and the exposed sections 31a, 32a, 33a, and 34a of the connection terminals 30 that are exposed from the first molded part 40 are connected by the solder 60.

Next, the first molded part 40, the internal components 10 and 20, the connection terminals 30, and the solder 60 shown in FIG. 7 are set in the mold device 100 for molding the second molded part 50.

The mold device 100 includes, for example, a lower support mold 101 that supports the first molded part 40 from the second face II side, an upper support mold 102 that supports the first molded part 40 from the first face I side, and a connection terminal support mold 103 that supports the connector exposed sections 33c and 34c (also including the connector exposed sections 31c and 32c, although not shown) exposed from the first molded part 40.

A leading end of a positioning pin 101a of the lower support mold 101 is held by a corresponding recess 41a of the first molded part 40. A leading end of a positioning pin 102a of the upper support mold 102 is held by a corresponding recess 41a of the first molded part 40. The connection terminal support mold 103 holds the connection terminals 30. Thus, even with the recesses 41a formed only in the head 41, the first molded part 40 is properly held by the mold device 100.

Note that the molds 101, 102, and 103 of the mold device 100 are described as examples, while the device for molding the molded component 1 is not limited to the above example of the mold device 100.

### Effect of the Above-Described Embodiment

Next, examples of the effect of the above-described embodiment will be described. In the following description, the effect is described based on the specific configurations described as examples in the above embodiment, but may be substituted by other specific configurations described as examples herein, to the extent that the same effect is produced.

This substitution may be made between a plurality of embodiments. In other words, the configurations described as examples in different embodiments may be combined to produce the same effect.

The molded component 1 configured as described above includes the first molded part 40 that covers the internal components 10 and 20 and holds the connection terminals 30, so that the first molded part 40 can be positioned using the through-holes (the outer through-holes 51a) formed only in the non-water-exposed region X. Further, the first molded part 40 is provided that covers the internal components 10 and 20 and holds the connection terminals 30, so that the positional relationship between the internal components 10 and 20 and the connection terminals 30 can be determined consistently. Less variation occurs in produced components.

Through-holes (the outer through-holes 51a) that extend from the outer side of the second molded part 50 to the first molded part 40 are formed in the non-water-exposed region X. This makes it unlikely for water to enter the outer through-holes 51a themselves, and thus also makes it unlikely for water to enter between the first molded part 40 and the second molded part 50. This suppresses water exposure of the internal components 10 and 20. Therefore, water exposure of the internal components 10 and 20 is suppressed regardless of where the through-holes (the inner through-holes 41b) for positioning the internal components 10 and 20 are formed in the first molded part 40.

The internal components 10 and 20 and the connection terminals 30 can be integrally molded, thereby reducing the overall production person-hours for the molded component 1.

With the molded component 1, the lead wires 12, 13, 22, and 23 and the connection terminals 30 have, in the joint section 43 of the first molded part 40, the respective exposed sections (the exposed sections 12a, 13a, 22a, and 23a of the lead wires 12, 13, 22, and 23, and the exposed sections 31a, 32a, 33a, and 34a of the connection terminals 31, 32, 33, and 34) that are exposed from the first molded part 40. This facilitates soldering work with the solder 60.

The lead wires 12, 13, 22, and 23 and the connection terminals 30 are connected by the solder 60, thereby providing a reliable connection therebetween.

The second molded part 50 covers the solder 60, thereby providing a more reliable connection between the lead wires 12, 13, 22, and 23 and the connection terminals 30.

The connection terminals 30 have the connector exposed sections 31c, 32c, 33c, and 34c, which are to be connected to a connector connectable to another electrical component. This is realized due to the first molded part 40 holding the connection terminals 30 at fixed positions suitable for connection with that connector.

The connector exposed sections 31c, 32c, 33c, and 34c of the connection terminals 30 serve as connectors to be connected to a connector of another electrical component. This eliminates the need for an electrical conductor such as an electric wire for interconnecting the molded component 1 and the connector. Thus, the molded component 1 itself serves as a connector. Furthermore, the configuration between the molded component 1 and a connector connectable to another electrical component can be simplified.

The non-water-exposed region includes a region covering the electronic component bodies (the detector element bodies 11 and 21), and through-holes (the outer through-holes 51a) are formed only in the region (the head cover 51) covering the head 41. The first molded part 40 has through-holes (the inner through-holes 41b) for passing the positioning pins for fixing the internal components 10 and 20 during molding. The inner through-holes 41b extend through the internal components 10 and 20 to the outside of the first molded part 40. Therefore, if water enters these inner through-holes 41b, the internal components 10 and 20 will also be exposed to the water. If the outer through-holes 51a are also formed in the region (the head cover 51) covering the head 41, the outer through-holes 51a and the inner through-holes 41b will be close to each other. It is considered that if the outer through-holes 51a and the inner through-holes 41b are close to each other, water entering from the outer through-holes 51a will easily pass through a gap between the second molded part 50 and the first molded part 40 and will be likely to enter the inner through-holes 41b. However, the outer through-holes 51a are formed in the non-water-exposed region X to suppress the entry of water into the outer through-holes 51a, and therefore the entry of water into the inner through-holes 41b is also suppressed.

Further, the through-holes (the outer through-holes 51a) formed in the second molded part 50 are formed only in the region (the head cover 51) covering the head 41, and are not formed in the other region. This eliminates the need to form through-holes at various locations in the second molded part 50, and can simplify the shape of the second molded part 50.

The O-ring 70 is attached to the outer periphery of the second molded part 50 and separates the non-water-exposed region X from the other region Y. That is, the non-water-exposed region X is provided by the waterproofing effect of the O-ring 70. The second molded part 50 has through-holes (the outer through-holes 51a) only in the non-water-exposed region X. This suppresses water exposure of the internal components 10 and 20.

Two or more through-holes (the outer through-holes 51a) are formed in one face (the first face I) of the molded component 1. That is, the second molded part 50 is fixed by attaching two or more positioning pins to the first face I when the second molded part 50 is molded. This suppresses rotation (misalignment) of an insert (the first molded part 40) when the second molded part 50 is molded.

### Other Embodiments

In the above-described embodiment, the O-ring 70 is used to suppress the entry of water into the non-water-exposed region X (the region where the outer through-holes 51a are formed), and the O-ring 70 separates the non-water-exposed region X from the other region (the water-exposed region Y). However, the non-water-exposed region X can also be separated from the other region (the water-exposed region Y) using a method other than the O-ring 70. For example, the surface of the aforementioned locking member 90 and the outer surface 83 (to which a sealing member may further be added) of the attachment target component 80 may be used, instead of the O-ring 70, to suppress the entry of water into the non-water-exposed region X (the region where the outer through-holes 51a are formed). In this case, the contact area between the surface of the locking member 90 and the outer surface 83 of the attachment target component 80 separates the non-water-exposed region X from the other region (the water-exposed region Y).

In the above-described embodiment, two internal components 10 and 20 are provided and parallel with each other, the number of internal components provided in the molded component may alternatively be one or three or more.

In the above-described embodiment, the lead wires 12, 13, 22, and 23 and the connection terminals 30 are connected by the solder 60 after the first molded part 40 has been molded. However, the lead wires 12, 13, 22, and 23 and the connection terminals 30 may alternatively be connected by the solder 60 before the first molded part 40 is molded. In this case, a configuration can be employed in which the lead wires 12, 13, 22, and 23 and the connection terminals 30 are not exposed in the joint section 43. This configuration can further simplify the shape of the first molded part 40.

In the above-described embodiment, the lead wires 12, 13, 22, and 23 and the connection terminals 30 are connected by the solder 60, but there is no limitation thereto The lead wires 12, 13, 22, and 23 and the connection terminals 30 may alternatively be connected by means of welding.

In the above-described embodiment, the first molded part 40 is molded with the internal components 10 and 20 as inserts. However, there is no limitation thereto. The internal components 10 and 20 need not necessarily be used as inserts when the first molded part 40 is molded. In this case, a configuration without the inner through-holes 41b can be employed. For example, a first molded part with recesses into which the internal components 10 and 20 are fittable may be molded separately from the internal components 10 and 20, and the internal components 10 and 20 may be fitted into those recesses of this first molded part.

In the above-described embodiment, the non-water-exposed region X including the region covering the electronic component bodies (the detector element bodies 11 and 21) is set. However, the non-water-exposed region X that does not include the region covering the electronic component bodies (the detector element bodies 11 and 21) may alternatively be set. For example, the non-water-exposed region X may be set in the joint section 53. In this case, the outer through-holes 51a are formed only in the joint section 53.

In the above-described embodiment, three outer through-holes 51a are formed on the first face I side, but a configuration in which one outer through-hole 51a is formed on the first face I side may alternatively be employed. In this case, it is preferable that the outer through-hole 51a has a shape other than a cylindrical or conic shape. For example, it is preferable that the outer through-hole 51a has a shape such as a polygonal-columnar shape or an elliptical-columnar shape. Further, the number of outer through-holes 51a formed on the first face I side may alternatively be any number of two or more except three. However, the smaller number of outer through-holes 51a is preferable since water may enter therethrough to reach the internal components 10 and 20.

### Modifications of the Above-Described Embodiments

In the embodiments described above, the properties of materials, materials, dimensions, shapes, relative positional relationships, or implementation conditions of each constituent element may also be described, but these are merely examples in all respects and are not limited to those described herein.

Thus, numerous variations and equivalents that are not illustrated are contemplated within the scope of the technology disclosed herein. For example, the scope of technology disclosed herein includes cases where at least one constituent element is modified. added. or omitted. and cases where at least one constituent element of at least one embodiment is extracted and combined with a constituent element of another embodiment.

1. A molded component comprising:
an internal component including:
an electronic component body; and
a lead wire extending from the electronic component body;
a connection terminal connected to the lead wire;
a first molded part covering the internal component and holding the connection terminal; and
a second molded part covering the first molded part,
wherein the second molded part has a non-water-exposed region located in a region where water exposure is suppressed, and
a through-hole extending from a surface of the second molded part to reach the first molded part is formed only in the non-water-exposed region of the second molded part.

2. The molded component according to claim 1,
wherein the first molded part includes:
a head covering the electronic component body;
a connection terminal holder holding a portion of the connection terminal; and
a joint section joining the head to the connection terminal holder,
the lead wire and the connection terminal each have, in the joint section, an exposed section exposed from the first molded part,
the exposed section of the lead wire and the exposed section of the connection terminal are connected to each other by solder in the joint section, and
the second molded part covers the exposed section of the lead wire, the exposed section of the connection terminal, and the solder connecting the exposed section of the lead wire and the exposed section of the connection terminal to each other, in the joint section.

3. The molded component according to claim 1,
wherein the connection terminal has a connector exposed section exposed from the first molded part and the second molded part, and
the connector exposed section is a connecting section to be connected to a connector connectable to another electrical component.

4. The molded component according to claim 1, wherein the non-water-exposed region includes a region covering the electronic component body.

5. The molded component according to claim 1,
wherein an O-ring is attached to an outer periphery of the second molded part, and
the O-ring separates the non-water-exposed region from a region other than the non-water-exposed region.

6. The molded component according to claim 1,
wherein the second molded part has a first face and a second face oriented in a direction opposite to a direction in which the first face is oriented,
the through-hole is formed in both the first face and the second face, and
the through-hole includes at least two through-holes formed in the first face.

7. The molded component according to claim 2,
wherein the connection terminal has a connector exposed section exposed from the first molded part and the second molded part, and
the connector exposed section is a connecting section to be connected to a connector connectable to another electrical component.

8. The molded component according to claim 2, wherein the non-water-exposed region includes a region covering the electronic component body.

9. The molded component according to claim 2,
wherein an O-ring is attached to an outer periphery of the second molded part, and
the O-ring separates the non-water-exposed region from a region other than the non-water-exposed region.

10. The molded component according to claim 2,
wherein the second molded part has a first face and a second face oriented in a direction opposite to a direction in which the first face is oriented,
the through-hole is formed in both the first face and the second face, and
the through-hole includes at least two through-holes formed in the first face.
